(19) United States
(12) Patent Application Publication
(10) Pub. No.: US 2024/0431185 A1
(43) Pub. Date: Dec. 26, 2024

(54) DISPLAY DEVICE

(71) Applicant: LG Display Co., Ltd., Seoul (KR)

(72) Inventors: Youngsub SHIN, Paju-si (KR); YoungHoon KIM, Paju-si (KR)

(73) Assignee: LG Display Co., Ltd., Seoul (KR)

(21) Appl. No.: 18/646,483

(22) Filed: Apr. 25, 2024

(30) Foreign Application Priority Data
Jun. 21, 2023 (KR) 10-2023-0079981

(51) Int. Cl. H10K 59/80; H10K 59/122; H10K 59/38; H10K 59/40; H10K 102/00

(52) U.S. Cl. CPC H10K 59/8792; H10K 59/122; H10K 59/38; H10K 59/40; H10K 59/873; H10K 2102/331

(57) ABSTRACT

Discussed is a display device including a substrate, a light emitting element positioned on the substrate, a bank dividing an emission area corresponding to the light emitting element and a non-emission area that is adjacent to the emission area, and including a first opening corresponding to the light emitting element, an encapsulation layer positioned on the light emitting element, a touch electrode positioned on the encapsulation layer, a first matrix positioned on the touch electrode and a second matrix positioned on the first matrix and having a lower refractive index than the first matrix, and a color filter positioned on the touch electrode.

### CROSS-REFERENCE TO RELATED APPLICATION

This application claims priority to Korean Patent Application No. 10-2023-0079981, filed in the Republic of Korea on Jun. 21, 2023, the entire contents of which is hereby expressly incorporated by reference into the present application.

### BACKGROUND

### Field

Embodiments of the disclosure relate to a display device.

### Discussion of Related Art

A display device can include an emission portion and a non-emission portion and can further include light emitting elements in multiple pixels along with various circuit elements for driving the light emitting elements in the multiple pixels. In such display devices, when an external light is reflected by various material layers constituting the light emitting elements and the various circuit element, a user of the display device can have difficulty in identifying information displayed on the display device due to the external light that has been internally reflected to interfere with light emitted from the light emitting elements.

Conventional display devices adopt a polarizing plate to effectively reduce the reflectance of the external light but can suffer from an increase in manufacturing costs of the display device due to use of an expensive polarizing plate, limitations to thinning the display device from use of the polarizing plate having a certain thickness, and need for using more power to implement a brightness that compensates for a brightness reduction occurring while light emitted from the light emitting element passes through the polarizing plate.

### SUMMARY OF THE DISCLOSURE

In the display technology art, there are being studied techniques for implementing a low reflectance without using a polarizing plate which is expensive and can significantly reduce the light emissions from the display device. However, when no polarizing plate is used, rainbow mura can be caused by the light reflected from the display device or, to prevent rainbow mura, an additional optical layer can be included, increasing costs and complicating the structure. Further, increased demand for display technology requires a technique that can be implemented even with smaller pixels to respond to a higher resolution, a lower reflectance for external light reflection, and inclusion of touch technology capable of external entry for use as an input device as well as a display device. The disclosure provides a touch input-type display device capable of low-power driving at lower costs by avoiding use of a polarizing plate, responding to high-resolution technology, and implementing a low reflectance compared with conventional display devices.

Embodiments of the disclosure can provide a display device having a matrix structure for reducing reflectance.

Embodiments of the disclosure can provide a display device capable of implementing low reflectance by including a matrix including a first layer and a second layer positioned on the first layer and having a lower refractive index than the first layer and positioning a color filter between a first matrix and a second matrix.

Embodiments of the disclosure can provide a display device comprising a substrate, a light emitting element positioned on the substrate, a bank including a first opening corresponding to the light emitting element, an encapsulation layer positioned on the light emitting element, a touch electrode positioned on the encapsulation layer, matrixes positioned on the touch electrode, and a color filter positioned on the touch electrode.

The matrix can include a first layer and a second matrix. The second matrix can be positioned on the first layer and can have a lower refractive index than the first layer. Further, the color filter can be positioned on the first layer and under the second layer.

According to embodiments of the disclosure, there can be provided a display device implementing low reflectance by including a matrix including a first layer and a second layer positioned on the first layer and having a lower refractive index than the first layer and a color filter positioned between the first layer and the second layer.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view schematically illustrating a configuration of a display device according to embodiments of the disclosure;

FIG. 2 is a view schematically illustrating a display panel of a display device according to embodiments of the disclosure;

FIG. 3 is a view illustrating an example structure in which a touch panel is embedded in a display panel according to embodiments of the disclosure;

FIG. 4 is a view illustrating a correlation between a mesh-type touch electrode area and a subpixel area in a display device according to embodiments of the disclosure;

FIG. 5 is a cross-sectional view illustrating a display device according to a comparative example of the disclosure;

FIGS. 6A and 6B are views illustrating effects of reflected light according to a comparative example and embodiments of the disclosure; and

FIGS. 7, 8, 9, and 10 are cross-sectional views illustrating a display device according to embodiments of the disclosure.

### DETAILED DESCRIPTIONS OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked””, or another component can intervene. Here, the other component can be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise).

Hereinafter, various embodiments of the disclosure are described in detail with reference to the accompanying drawings.

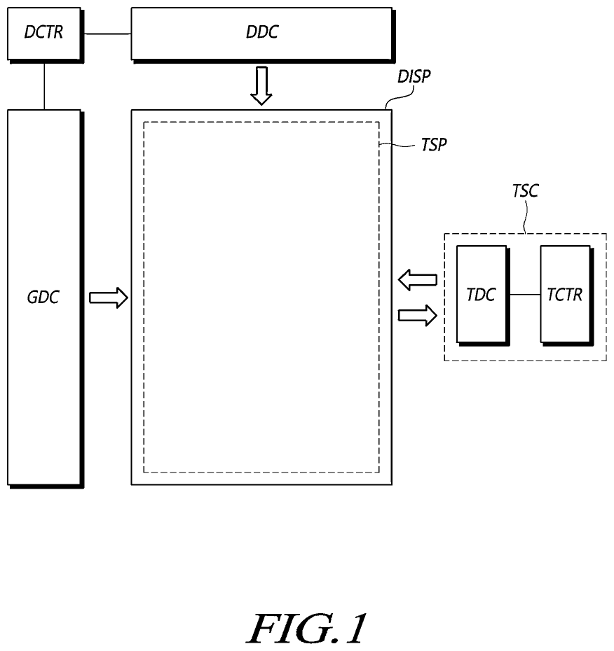

FIG. 1 is a view schematically illustrating a configuration of a display device according to an embodiment. All components of each display device according to all embodiments of the disclosure are operatively coupled and configured.

Referring to FIG. 1, a display device according to an embodiment can provide both a function for image display and a function for touch sensing.

To provide the image display function, the display device according to an embodiment can include a display panel DISP having a plurality of data lines and a plurality of gate lines disposed thereon and having a plurality of subpixels defined by the plurality of data lines and the plurality of gate lines arranged thereon, a data driving circuit DDC driving the plurality of data lines, a gate driving circuit GDC driving the plurality of gate lines, and a display controller DCTR controlling the operation of the data driving circuit DDC and the gate driving circuit GDC.

Each of the data driving circuit DDC, gate driving circuit GDC, and display controller DCTR can be implemented as one or more individual components. In some cases, two or more of the data driving circuit DDC, the gate driving circuit GDC, and the display controller DCTR can be integrated and implemented as one component. For example, the data driving circuit DDC and the display controller DCTR can be implemented as one integrated circuit chip (IC Chip).

To provide the touch sensing function, the display device according to an embodiment can include a touch panel TSP including a plurality of touch electrodes and a touch sensing circuit TSC for supplying a touch driving signal to the touch panel TSP, detecting a touch sensing signal from the touch panel TSP, and sensing the presence or absence of a user's touch or a touch position (or coordinates of touch) on the touch panel TSP based on the detected touch sensing signal.

For example, the touch sensing circuit TSC can include a touch driving circuit TDC supplying a touch driving signal to the touch panel TSP and detecting a touch sensing signal from the touch panel TSP and a touch controller TCTR sensing the presence or absence of the user's touch and/or the position of touch on the touch panel TSP based on the touch sensing signal detected by the touch driving circuit TDC.

The touch driving circuit TDC can include a first circuit part supplying a touch driving signal to the touch panel TSP and a second circuit part detecting a touch sensing signal from the touch panel TSP.

The touch driving circuit TDC and the touch controller TCTR can be implemented as separate components or, in some cases, can be integrated and implemented as one component. Meanwhile, each of the data driving circuit DDC, gate driving circuit GDC and touch driving circuit TDC can be implemented as one or more integrated circuits and, in terms of electrical connection with the display panel DISP, be implemented in a chip-on-glass (COG) type, a chip-on-film (COF) type, or a tape carrier package (TCP) type. The gate driving circuit GDC can also be implemented in a gate-in-panel (GIP) type. But embodiments of the disclosures are not limited thereto.

Meanwhile, each of the circuit components DDC, GDC, and DCTR for display driving and the circuit components TDC and TCTR for touch sensing can be implemented as one or more individual components. In some cases, one or more of the circuit components DDC, GDC, and DCTR for display driving and one or more of the circuit components TDC and TCTR for touch sensing can be functionally integrated and implemented as one or more components. For example, the data driving circuit DDC and the touch driving circuit TDC can be implemented by being integrated into one or more integrated circuit chips. When the data driving circuit DDC and the touch driving circuit TDC are integrated into two or more integrated circuit chips, each of the two or more integrated circuit chips can have a data driving function and a touch driving function.

Meanwhile, the display device according to an embodiment can be of various types, such as an organic light emitting display device, an inorganic light emitting display device, and a liquid crystal display device. Hereinafter, for convenience of description, the display device is described as an organic light emitting display device as an example. In other words, the display panel DISP can be of various types, such as an organic light emitting display panel, an inorganic light emitting display panel, and a liquid crystal display panel, but hereinafter, for convenience of description, the display panel DISP is described as being an organic light emitting display panel as an example. But embodiments of the disclosures are not limited thereto.

Meanwhile, as is described below, the touch panel TSP can include a plurality of touch electrodes where a touch driving signal can be applied or a touch sensing signal can be detected, and a plurality of touch electrode lines for connecting the plurality of touch electrodes to the touch driving circuit TDC.

The touch panel TSP can be present outside the display panel DISP. In other words, the touch panel TSP and the display panel DISP can be separately manufactured and combined. Such a touch panel TSP is referred to as an external type or an add-on type.

Alternatively, the touch panel TSP can be embedded inside the display panel DISP. In other words, when manufacturing the display panel DISP, the touch sensor structure, such as the plurality of touch electrodes and the plurality of touch electrode lines constituting the touch panel TSP, can be formed together with electrodes and signal lines for display driving. Such a touch panel TSP is referred to as an embedded type. Hereinafter, for convenience of description, an example in which the touch panel TSP is an embedded type is described.

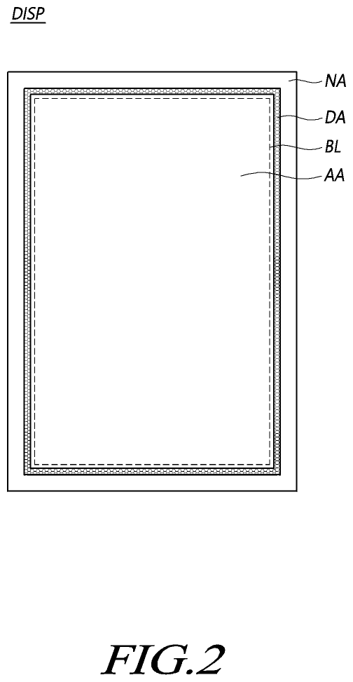

FIG. 2 is a view schematically illustrating a display panel of a display device according to an embodiment.

Referring to FIG. 2, the display panel DISP can include a display area AA where an image is displayed and a non-display area NA which is an outer area surrounding the outer boundary line BL of the display area AA.

In the display area AA of the display panel DISP, a plurality of subpixels for image display and various electrodes or signal lines for display driving are disposed. Further, a plurality of touch electrodes for touch sensing and a plurality of touch electrode lines electrically connected thereto can be disposed in the display area AA of the display panel DISP. Accordingly, the display area AA can also be referred to as a touch sensing area where touch sensing is possible.

In the non-display area NA of the display panel DISP, link lines extending from various signal lines disposed in the display area AA or link lines electrically connected with various signal lines disposed in the display area AA and pads electrically connected with the link lines are disposed. The pads disposed in the non-display area NA can be bonded to or electrically connected to display driving circuits (DDC, GDC, etc.).

In the non-display area NA of the display panel DISP, link lines extending from the plurality of touch electrode lines disposed in the display area AA or link lines electrically connected with the plurality of touch electrode lines disposed in the display area AA and pads electrically connected with the link lines are disposed. The pads disposed in the non-display area NA can be bonded to or electrically connected to the touch driving circuit TDC.

The non-display area NA can have an extension from a portion of the outermost touch electrode among the plurality of touch electrodes disposed in the display area AA and can further have one or more electrodes (touch electrodes) formed of the same material as the plurality of touch electrodes disposed in the display area AA.

In other words, the plurality of touch electrodes disposed on the display panel DISP can be all present in the display area AA, or some (e.g., outermost touch electrodes) among the plurality of touch electrodes disposed on the display panel DISP can be present in the non-display area NA, or some (e.g., outermost touch electrodes) among the plurality of touch electrodes disposed on the display panel DISP can be present in both the display area AA and the non-display area NA.

Meanwhile, referring to FIG. 2, the display panel DISP of the display device according to an embodiment can include a dam area DA for preventing a certain layer (e.g., encapsulation layer in an organic light emitting display panel) in the display area AA from collapsing.

The dam area DA can be positioned at a boundary between the display area AA and the non-display area NA or at any one point of the non-display area NA, which is an area outside the display area AA. The dam disposed in the dam area DA can be disposed while surrounding the display area AA in all directions or be disposed only outside one or two or more portions (e.g., portions with a layer that is easy to collapse) of the display area AA. The dams disposed in the dam area DA can have a single pattern connected to each other or two or more disconnected patterns. Further, only a first dam can be disposed in the dam area DA, or two dams (first dam and second dam) can be disposed. Three or more dams can be disposed in other embodiments, but embodiments of the disclosures are not limited thereto. Only the first dam can be present in any one direction in the dam area DA, and the first dam and the second dam both can be present in any one other direction. But embodiments of the disclosures are not limited thereto.

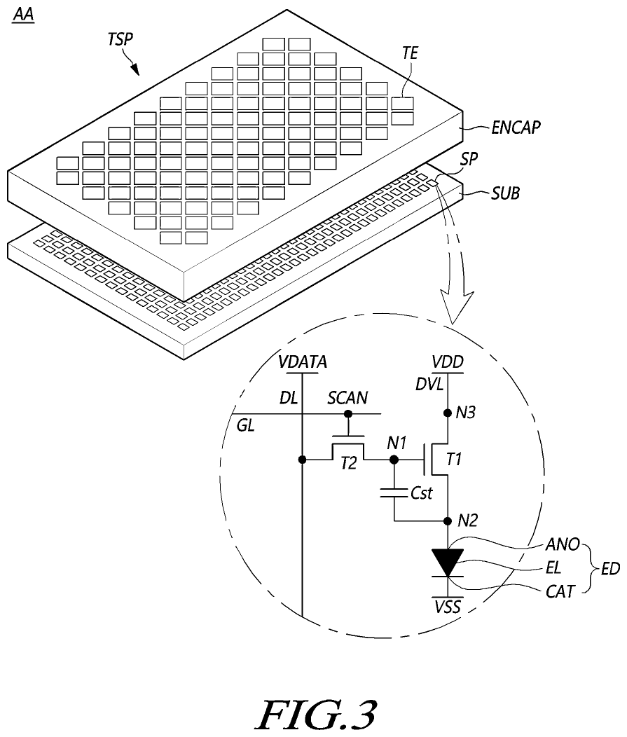

FIG. 3 is an example view illustrating a structure in which a touch panel is embedded in a display panel according to an embodiment.

Referring to FIG. 3, a plurality of subpixels SP are arranged on a substrate SUB in the display area AA of the display panel DISP.

Each subpixel SP can include a light emitting element ED, a first transistor T1 for driving the light emitting element ED, a second transistor T2 for transferring a data voltage VDATA to a first node N1 of the first transistor T1, and a storage capacitor Cst for maintaining a predetermined voltage during one frame.

The first transistor T1 can include a first node N1 to which the data voltage VDATA can be applied, a second node N2 electrically connected with the light emitting element ED, and a third node N3 to which a driving voltage VDD is applied from a driving voltage line DVL. The first node N1 can be the gate node, the second node N2 can be the source node or the drain node, and the third node N3 can be the drain node or the source node. Such a first transistor T1 is also referred to as a driving transistor for driving the light emitting element ED.

The light emitting element ED can include an anode electrode ANO, a light emitting layer EL, and a cathode electrode CAT. The anode electrode ANO can be electrically connected to the second node N2 of the first transistor T1, and a base voltage (or driving low voltage) VSS can be applied to the cathode electrode CAT. In this light emitting element ED, the light emitting layer EL can be an organic light emitting layer including an organic material. In this case, the light emitting element ED can be an organic light emitting diode OLED.

The second transistor T2 can be controlled for on/off by the scan signal SCAN applied through the gate line GL, and be electrically connected between the first node N1 of the first transistor T1 and the data line DL. The second transistor T2 is also referred to as a switching transistor. When the second transistor T2 is turned on by the scan signal SCAN, it transfers the data voltage VDATA supplied from the data line DL to the first node N1 of the first transistor T1.

The storage capacitor Cst can be electrically connected between the first node N1 and the second node N2 of the first transistor T1.

As shown in FIG. 3, each subpixel SP can have a 2TIC structure including two transistors T1 and T2 and one capacitor Cst and, in some cases, can further include one or more transistors or one or more capacitor. But embodiments of the disclosures are not limited thereto.

The storage capacitor Cst can be not a parasitic capacitor (e.g., Cgs or Cgd) that is an internal capacitor that can exist between the first node N1 and the second node N2 of the first transistor T1, but an external capacitor intentionally designed outside the first transistor T1. But embodiments of the disclosures are not limited thereto.

Each of the first transistor T1 and the second transistor T2 can be an n-type transistor or a p-type transistor.

Meanwhile, as described above, circuit elements, such as a light emitting element ED, two or more transistors T1 and T2, and one or more capacitors Cst, are disposed on the display panel DISP. Since the circuit elements (in particular, light emitting element ED) are vulnerable to external moisture or oxygen, an encapsulation layer ENCAP can be disposed on the display panel DISP to prevent external moisture or oxygen from penetrating into the circuit elements (in particular, light emitting element ED). The encapsulation layer ENCAP can be formed of one or more layers.

Meanwhile, in the display device according to an embodiment, the touch panel TSP can be formed on the encapsulation layer ENCAP. In other words, in the display device, the touch sensor structure, such as a plurality of touch electrodes TE constituting the touch panel TSP, can be disposed on the encapsulation layer ENCAP.

During touch sensing, a touch driving signal or a touch sensing signal can be applied to the touch electrode TE. Therefore, during touch sensing, a potential difference can be formed between the touch electrode TE and the cathode electrode CAT disposed with the encapsulation layer ENCAP interposed therebetween, causing unnecessary parasitic capacitance. The parasitic capacitance can generate noise and lower touch sensitivity. Thus, to lower the parasitic capacitance, a separate electrode (i.e., shielding electrode) can be placed between the touch electrode TE and the cathode electrode CAT, shielding the noise generated between the touch electrode TE and the cathode electrode CAT.

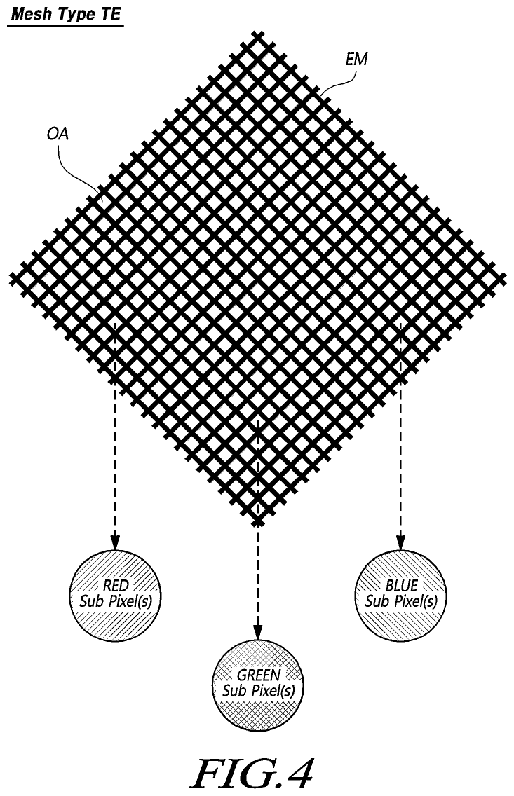

FIG. 4 is a view illustrating a correlation between an area of a mesh-type touch electrode TE and a subpixel area in a display device 100 according to embodiments.

Referring to FIG. 4, in a display device 100 according to embodiments, each of a plurality of touch electrodes TE can be an electrode metal EM that is patterned in a mesh type to have holes OA. Here, the hole OA is also referred to as an open area.

In the touch electrode TE formed by patterning the electrode metal EM in a mesh type, each of the holes OA can correspond to an emission portion of one or more subpixels.

For example, when the display panel PNL is an LCD panel, the emission portion of the subpixel can include a pixel electrode, a color filter, or the like. When the display panel PNL is an OLED panel, the emission portion of the subpixel can include an anode electrode, an organic light emitting layer, etc. of an organic light emitting diode OLED, and in some cases, can include a color filter, etc. But embodiments of the disclosure are not limited thereto.

As described above, as the electrode metal EM of the touch electrode TE is patterned so that the emission portion of one or more subpixels is present corresponding to the position of each open area OA which is present in the touch electrode TE when viewed in plan view, the light emitting efficiency of the display panel PNL can be increased although the electrode metal EM is formed of an opaque material.

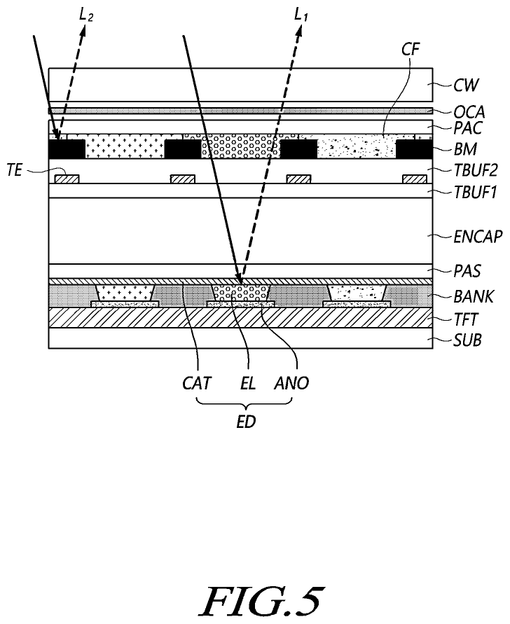

FIG. 5 is a cross-sectional view of a display device according to a comparative example of the disclosure, and is a view exemplarily illustrating positions of a color filter and a black matrix.

Referring to FIG. 5, the cathode electrode CAT of the organic light emitting diode ED can be present under the encapsulation layer ENCAP.

The thickness T of the encapsulation layer ENCAP can be, e.g., 5 micrometers or more. But embodiments of the disclosure are not limited thereto.

As described above, by designing the encapsulation layer ENCAP to have a thickness of 5 micrometers or more, the parasitic capacitance formed between the cathode electrode CAT of the organic light emitting diode ED and the touch electrodes TE can be reduced. Accordingly, it is possible to prevent a decrease in touch sensitivity due to parasitic capacitance.

Meanwhile, each of the plurality of touch electrodes TE can be patterned in a mesh shape (net shape) where the electrode metal EM has a plurality of open areas OA, and one or more subpixels or emission portions thereof can be present in the plurality of open areas OA when viewed in the vertical direction.

As described above, as the electrode metal EM of the touch electrode TE is patterned so that the emission portion of one or more subpixels is present corresponding to the position of each open area OA which is present in the touch electrode TE when viewed in plan view, the aperture ratio and light emitting efficiency of the display panel PNL can be increased.

Accordingly, as illustrated in FIG. 5, the position of the black matrix BM overlaps the position of the electrode metal EM of the touch electrode TE.

As the plurality of color filters CF are positioned at positions corresponding to the positions of the plurality of open areas OA, it is possible to provide an organic light emitting display panel and a display device having excellent light emitting performance.

The vertical positional relationship between the color filters CF and the touch electrodes TE is as follows.

As illustrated in FIG. 5, the plurality of color filters CF and the black matrix BM can be positioned on the plurality of touch electrodes TE.

In other words, the color filters CF can be positioned on the encapsulation layer ENCAP and can be positioned on a touch sensor metal such as a touch electrode TE and a touch line TL.

The plurality of color filters CF and the black matrix BM can be positioned on a first touch buffer layer TBUF1 and a second touch buffers TBUF2 on the plurality of touch electrodes TE.

As described above, it is possible to provide an OLED display-type display device having an optimal positional relationship between the color filters CF and the touch electrodes TE considering display performance such as light emitting performance and touch performance.

Meanwhile, attempts have conventionally been made to embed a touch panel TSP formed of touch electrodes TE into the display panel PNL in order to enhance manufacturing convenience and reduce the size of the display device.

However, it is quite difficult or limited to embed the touch panel TSP in the display panel PNL, which is an organic light emitting display panel.

For example, when manufacturing the display panel PNL, which is an organic light emitting display panel, there is a limitation in that a high-temperature process for forming touch electrodes TE, which are generally formed of a metal material, inside the panel is not free due to the organic material.

Due to such restrictions to structural characteristics and processes of the organic light emitting display panel, it is difficult to arrange the touch electrodes TE as touch sensors inside the display panel PNL which is an organic light emitting display panel. Accordingly, conventionally, a touch structure has been implemented by attaching the touch panel TSP to the display panel PNL, which is an organic light emitting display panel, rather than embedding the touch panel TSP in the display panel PNL, which is an organic light emitting display panel.

However, there can be provided a display panel PNL which is an organic light emitting display panel embedding a touch panel TSP with excellent display performance and touch performance through a touch on encapsulation layer (TOE) structure in which touch electrodes TE are formed on an encapsulation layer ENCAP and a color on encapsulation layer (COE) structure in which color filters CF are formed on an encapsulation layer ENCAP as shown in FIG. 5.

Referring further to FIG. 5, the display device according to the comparative example can include a substrate SUB, a thin film transistor layer TFT, a bank BANK, an encapsulation layer ENCAP, a first touch buffer layer TBUF1, a touch electrode TE, a second touch buffer layer TBUF2, a black matrix BM, and a color filter CF. But embodiments of the disclosure are not limited thereto.

The first touch buffer layer TBUF1 and the second touch buffer layer TBUF2 can be formed of an inorganic insulation layer and, as an insulation layer including silicon, can be SiNx, SiOx, or SiON, but is not limited thereto.

External light incident on the display device can be reflected from various parts of the display device. For example, L1 is external light reflected from the emission area of the light emitting element, and L2 is external light reflected from the black matrix.

The touch electrode TE and the touch line TL can be formed of a metal such as Cu, Mo, Ti, or Al, or an oxide-type transparent metal including indium. When the electrodes are formed of a metal material, the reflectance is high. Therefore, in order to prevent such reflection on metal, the touch electrode TE and the touch line TL can be positioned under the black matrix BM to prevent reflection of external light. The color filters CF can be formed to correspond to the open area OA of FIG. 4, and part of the color filter can be formed on the black matrix BM. But embodiments of the disclosure are not limited thereto.

The color filter CF should be formed corresponding to the open area OA for the corresponding color, and should not be formed in adjacent different colors to display only the desired color in the corresponding pixel, so that an end of the color filter can be formed on the black matrix BM.

An organic insulation layer PAC, an optical adhesive layer OCA, and a cover window CW can be further included on the black matrix BM and the color filter CF. The optical adhesive layer OCA can be positioned under the cover window CW and can be in direct contact with the cover window and have adhesiveness. But embodiments of the disclosure are not limited thereto.

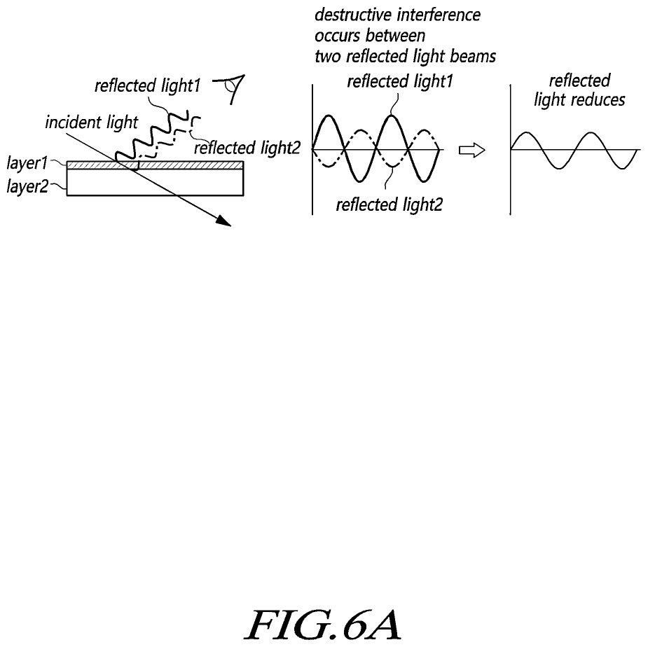

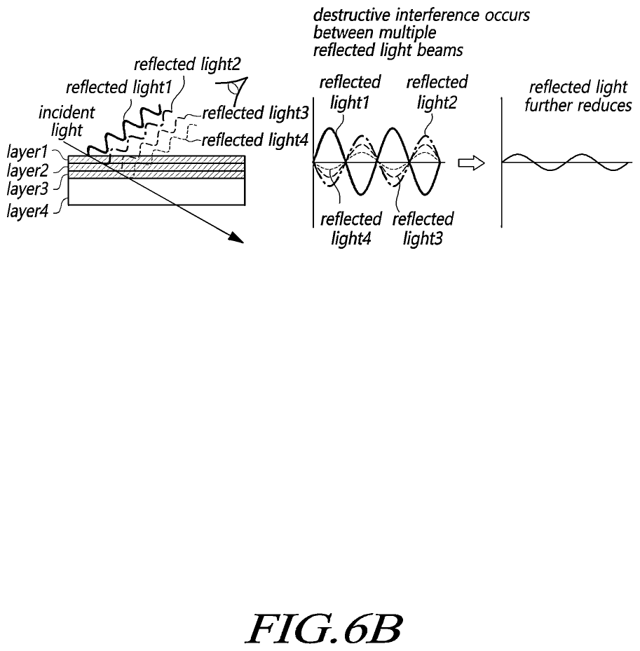

FIGS. 6A and 6B are views illustrating a case where incident light is reflected on a general multilayer film.

FIG. 6A is a view illustrating a process where incident light is reflected when two layers are configured. Since light can be reflected at the interface between two objects with different refractive indexes, reflected light 1 which is reflection of incident light at the first layer (layer 1) can be generated at two layers as shown in FIG. 6A, and reflected light 2 which is reflection at the interface where the light transmitted through the first layer (layer 1) meets the second layer (layer 2) can be generated. As such, two different reflected light beams can be generated. In this case, the phases of the reflected light 1 and the reflected light 2 can vary due to the distance difference, and two reflected light beams of different phases can be combined to cause destructive interference with each other. When such destructive interference occurs, the reflected light can have a smaller amplitude than the existing reflected light 1, and thus the reflected light can be reduced.

Such reflection on a multilayer film is a common phenomenon that occurs at two or more layers. When a quadruple-layer film is configured as shown in FIG. 6B, more reflected light than in FIG. 6A can be generated, and if the phase difference between the reflected light beams is adjusted, the reflected light can be further reduced than when the reflected light is reduced by two layers, due to destructive interference between several reflected light beams.

In FIG. 5, the external light L2 reflected from the black matrix BM can be reflected light on a single layer, which is formed by reflection by the black matrix BM, or can be the sum of the reflected light beams on two layers, which are generated by a combination of the reflected light generated on the color filter CF formed on the black matrix BM and the light that is transmitted through the color filter and then reflected by the black matrix BM.

As described above, when no polarizing plate is used, the visibility of the display area AA can be reduced by the reflected light. Thus, to address such phenomenon, pigment can be added to the optical adhesive layer or the overcoat layer positioned between the color filter CF and the cover window CW. However, adding pigment to the overcoat layer or the optical adhesive layer is still insufficient to reduce the reflectance of the display device.

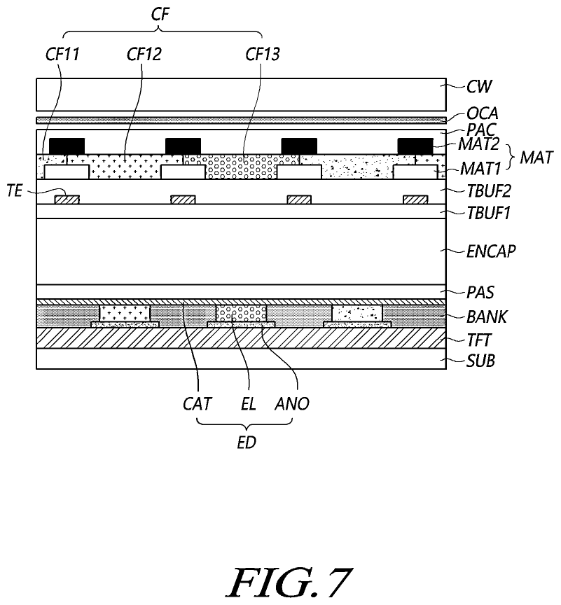

FIGS. 7 to 10 are cross-sectional views illustrating a display device according to embodiments of the disclosure.

Referring to FIGS. 7 to 10, a display device can include a substrate SUB, a light emitting element ED, a bank BANK, an encapsulation layer ENCAP, a touch electrode TE, a matrix MAT, and a color filter CF. Further, the display device can include a thin film transistor layer TFT positioned on the substrate SUB and on which a thin film transistor driving the light emitting element ED is positioned, a first touch buffer layer TBUF1 positioned on the encapsulation layer ENCAP, a second touch buffer layer TBUF2 positioned on the touch electrode TE, and an organic insulation layer PAC and an optical adhesive layer OCA positioned on the color filter CF. But embodiments of the disclosure are not limited thereto.

The substrate SUB can include a display area. A plurality of light emitting elements ED can be positioned in the display area. The thin film transistor layer TFT can be positioned on the substrate SUB. The thin film transistor layer TFT can be a layer where transistors driving the light emitting element ED are positioned. The light emitting element ED can be positioned on the substrate SUB. The light emitting element ED can be electrically connected to and driven by a transistor positioned on the thin film transistor layer TFT. The light emitting element ED can include an anode electrode ANO, a light emitting layer EL, and a cathode electrode CAT. But embodiments of the disclosure are not limited thereto.

The bank BANK can be positioned on the substrate SUB. Further, the bank BANK can be positioned on the thin film transistor layer TFT, and a portion of the bank BANK can be positioned on the anode electrode ANO of the light emitting element ED. The emission area and the non-emission area are divided by the bank BANK, and the emission area of the subpixel can be defined. The emission area of the subpixel can be an area where the bank BANK is opened, and can be an area where the anode electrode ANO of the light emitting element ED is exposed. But embodiments of the disclosure are not limited thereto.

The bank BANK can have a bank width BK_W of a predetermined size and can include a first opening O1 corresponding to the light emitting layer EL. When the first opening O1 corresponds to the light emitting layer EL, it can mean that the first opening O1 is positioned so that light generated from the light emitting layer EL of the light emitting element ED can be directed to the outside of the display device through the first opening O1. An emission area can be defined by the first opening O1 of the bank BANK, and the first opening O1 area of the bank BANK and the emission area can be the same. But embodiments of the disclosure are not limited thereto.

The inorganic insulation layer PAS and the encapsulation layer ENCAP can be positioned on the light emitting element ED. As the inorganic insulation layer PAS and the encapsulation layer ENCAP are positioned on the light emitting element ED, the light emitting element ED can be protected from external oxygen and moisture.

The touch electrode TE can be positioned on the encapsulation layer ENCAP. The first touch buffer layer TBUF1 can be positioned between the touch electrode TE and the encapsulation layer ENCAP, and on the first touch buffer layer TBUF1, the touch electrode TE can have the width TE_W of the touch electrode having a predetermined size and can include a second opening O2. The second opening O2 of the touch electrode TE can refer to the hole OA described above with reference to FIG. 4. The first opening O1 of the bank BANK can be positioned in or overlapped with the second opening O2 of the touch electrode TE. The touch electrode TE can be positioned on a non-emission area defined by the bank BANK and can be positioned to overlap the bank BANK. But embodiments of the disclosure are not limited thereto.

The width TE_W of the touch electrode can be equal to or smaller than the width BK_W of the bank, and the second opening O2 can be equal to or larger than the first opening O1. Due to this size difference, it is possible to minimize the blocking of light due to the touch electrode when light generated in the emission area is emitted to the outside.

The matrix MAT can be positioned on the touch electrode TE. The second touch buffer layer TBUF2 can be positioned between the touch electrode TE and the matrix MAT, but the second touch buffer layer TBUF2 need not be positioned as being necessary. As the matrix MAT is positioned to overlap the touch electrode TE on the second touch buffer layer TBUF2, the display device can be prevented from having high reflectance due to reflection of external light on the touch electrode TE.

The matrix MAT can include a first matrix MAT1 and a second matrix MAT2. The second matrix MAT2 can be positioned on the first matrix MAT1. Further, the second matrix MAT2 can have a lower refractive index than the first matrix MAT1. But embodiments of the disclosure are not limited thereto.

The first matrix MAT1 can have a width MAT1_W of the first matrix having a predetermined size and can include a third opening O3. The third opening O3 of the first matrix MAT1 can be positioned in or overlapped with the second opening O2 of the touch electrode TE, and the first opening O1 of the bank BANK can be positioned in or overlapped with the third opening O3 of the first matrix MAT1. The first matrix MAT1 can be positioned on a non-emission area defined by the bank BANK and can be positioned to overlap the bank BANK and the touch electrode TE.

The width MAT1_W of the first matrix MAT1 can be equal to or larger than the width TE_W of the touch electrode and can be equal to or smaller than the width BK_W of the bank, and the third opening O3 of the first matrix MAT1 can be equal to or larger than the first opening O1 of the bank BANK and can be equal to or smaller than the second opening O2 of the touch electrode TE.

The first matrix MAT1 can include white nanoparticles. The white nanoparticles can include particles composed of oxide, and can be composed of titanium-based oxides such as rutile, anatase, and titania, or silicon nanoparticles, but are not limited thereto. The first matrix MAT1 can include a binder, a photosensitive agent, and an additive in addition to white nanoparticles. The first matrix MAT1 can be formed by a low temperature process of 100° C. or less. The first matrix MAT1 can include black nanoparticles instead of white nanoparticles, or the first matrix MAT1 can further include black nanoparticles together with white nanoparticles. The “black nanoparticles” mentioned in the disclosure can be referred to as black particles. Further, the term “black” mentioned in the disclosure can mean a color that is effective in absorbing (or blocking) light, can be pure black, or can be various dark colors similar to black even if it is not pure black. Embodiments of the disclosures are not limited thereto.

The color filter CF can be positioned on the touch electrode TE. The color filter CF can fill the third opening O3 of the first matrix MAT1 and can include color filter patterns corresponding to the color of light emitted from the light emitting element.

Referring to FIGS. 7 to 10, a portion of the color filter CF can be positioned on the first matrix MAT1, and the color filter CF can have a lower refractive index than the first matrix MAT1. But embodiments of the disclosure are not limited thereto.

The second matrix MAT2 can be positioned on the first matrix MAT1 to overlap the first matrix MAT1 and the touch electrode TE.

The second matrix MAT2 can have a width MAT2_W of the second matrix having a predetermined size and can include a fourth opening O4. The fourth opening O4 of the second matrix MAT2 can be positioned in or overlapped with the second opening O2 of the touch electrode TE, and the third opening O3 of the first matrix MAT1 and the first opening O1 of the bank BANK can be positioned in the fourth opening O4 of the second matrix MAT2. The second matrix MAT2 can be positioned in a non-emission area rather than an emission area defined by the bank BANK, and can be positioned to overlap the bank BANK, the touch electrode TE, and the first matrix MAT1.

The width MAT2_W of the second matrix MAT2 can be equal to or larger than the width TE_W of the touch electrode, equal to or smaller than the width BK_W of the bank, and equal to or smaller than the width MAT1_W of the first matrix MAT1. The fourth opening O4 of the second matrix MAT2 can be equal to or larger than the first opening O1 of the bank BANK, equal to or smaller than the second opening O2 of the touch electrode TE, and equal to or larger than the third opening O3 of the first matrix MAT1. But embodiments of the disclosure are not limited thereto.

The second matrix MAT2 can include black nanoparticles. The black nanoparticles can include particles composed of carbon black or lactam black, but are not limited thereto. The second matrix MAT2 can include a binder, a photosensitive agent, and an additive in addition to the black nanoparticles. The second matrix MAT2 can be formed by a low temperature process of 100° C. or less. The black nanoparticles included in the second matrix MAT2 can have a larger weight ratio than the black nanoparticles included in the first matrix MAT1. But embodiments of the disclosure are not limited thereto.

A portion of the color filter CF is positioned on the first matrix MAT1, and the color filter CF positioned on the first matrix MAT1 is positioned under the second matrix MAT2.

As illustrated in FIGS. 7 to 10, when the first matrix MAT1, the color filter CF, the second matrix MAT2, and the second touch buffer layer TBUF2 are positioned on the touch electrode TE to correspond to the touch electrode TE, the light incident from the outside and reflected from the touch electrode TE can generate a plurality of reflected light beams as illustrated in FIG. 6B, and when destructive interference occurs, the reflected light can be further reduced. When the refractive index of the first matrix MAT1 positioned at the lower portion is high and the refractive index of the second matrix MAT2 positioned at the upper portion is low, the reflectance of external light can be further lowered.

In order to obtain such low reflection of external light, the refractive index of the first matrix MAT1 can be 2.1 to 2.7, and the refractive index of the second matrix MAT2 can be 1.4 to 1.8. But embodiments of the disclosure are not limited thereto.

An organic insulation layer PAC, an optical adhesive layer OCA (which may also called as an organic layer), and a cover window CW (which may also be called as a second substrate) can be further included on the second matrix MAT2 and the color filter CF. The optical adhesive layer OCA can be positioned under the cover window CW and can be in direct contact with the cover window and have adhesiveness. The optical adhesive layer OCA can include pigment and dye capable of reducing reflectance. The pigment and dye capable of reducing reflectance can be a mixture of black or red and blue, and when such pigment and dye capable of reducing reflectance are included, the display device can have a lower reflectance.

Table 1 below shows comparison in reflectance between display devices according to an embodiment of the disclosure and a comparative example.

TABLE 1

| | reflectance (%) | | |
|---|---|---|---|
| Material comparison | 450 nm | 550 nm | 650 nm |
| comparative example | 4.8 | 5.4 | 7.4 |
| embodiment | 4.2 | 4.2 | 4.2 |

In Table 1, the comparative example is the reflectance of the display device having the black matrix BM and the color filter CF structure illustrated in FIG. 5, and the embodiment is the reflectance of the display device according to the embodiment of FIG. 7. As described above, since greater destructive interference can be caused when more multilayer films are applied, it can be identified that the external light L2 reflected from the black matrix BM is affected by greater destructive interference in the embodiment of FIG. 7 than in the comparative example of FIG. 5, and thus has a lower reflectance in all measured wavelength bands.

Referring to FIGS. 7 to 10, when the second matrix MAT2 is positioned on the first matrix MAT1, one or more of the color filters CF can be interposed between the second matrix MAT2 and the first matrix MAT1. For example, in various embodiments of the disclosure, lateral portions of the color filters CF can be interposed between the second matrix MAT2 and the first matrix MAT1, while main portions of the color filters CF are located in the fourth opening O4. In embodiments of the disclosure, the main portions of the color filters CF are different in thickness from the lateral portions of the color filters CF.

Referring to FIGS. 7 to 10, a first thickness of the lateral portions of the color filters CF can be thicker than a second thickness of the main portions of the color filters CF. In various embodiments of the disclosure, the lateral portions of the color filters CF can have the same thickness from each other, but embodiments of the disclosure are not limited thereto. For example, the lateral portions of the color filters CF can have different thicknesses depending on the color of the color filters CF. Also, in various embodiments of the disclosure, the main portions of the color filters CF can have the same thickness from each other, but embodiments of the disclosure are not limited thereto. For example, the main portions of the color filters CF can have different thicknesses depending on the color of the color filters.

Referring to FIGS. 7 to 10, a thickness of the second matrix MAT2 can be the same or constant throughout the display area AA. Also, a thickness of the first matrix MAT1 can be the same or constant throughout the display area AA. But embodiments of the disclosure are not limited thereto. For example, at least one of a thickness of the first matrix MAT1 and a thickness of the second matrix MAT2 can vary along a width of the first matrix MAT1 or a width of the second matrix MAT2. In various embodiments of the disclosure, the thickness of the first matrix MAT1 and the thickness of the second matrix MAT2 can be the same or different.

Referring to FIGS. 7 to 10, a thickness of the organic insulation layer PAC can vary along a surface of the display area AA of the display panel DISP. For example, in embodiments of the disclosure, the organic insulation layer PAC is one both the second matrix MAT2 and the color filters CF. In this regard, the thickness of the organic insulation layer PAC can differ between a portion of the organic insulation layer PAC that directly overlaps the second matrix MAT2 and a portion of the organic insulation layer PAC that directly overlaps the color filters CF. For example, the thickness of the portion of the organic insulation layer PAC that directly overlaps the second matrix MAT2 can be less than the portion of the organic insulation layer PAC that directly overlaps the color filters CF. Additionally, when the organic insulation layer PAC directly overlaps the color filters CF, thicknesses of portions of the organic insulation layer PAC that directly overlap the color filters CF can vary depending on the colors of the color filters CF or locations of the portions of the organic insulation layer PAC on a surface of the display area AA.

Referring to FIGS. 7-10, the color filters CF are provided with respective upper surfaces that contact respective lower surfaces of the second matrix MAT2 so that the upper surfaces of the color filters CF are coplanar with the lower surfaces of the second matrix MAT2, but embodiments of the disclosure are not limited thereto. In other embodiments of the disclosure, the respective upper surfaces of the second matrix MAT2 can be aligned or coplanar with respective upper surfaces of the color filters CF. When the upper surfaces of the second matrix MAT2 and the upper surfaces of the color filters CF are aligned or coplanar, the organic insulation layer PAC can have a contestant thickness across the surface of the display area AA, but embodiments of the disclosure are not limited thereto, and the organic insulation layer PAC can have different thicknesses across the surface of the display area AA when the upper surfaces of the second matrix MAT2 and the upper surfaces of the color filters CF are aligned or coplanar.

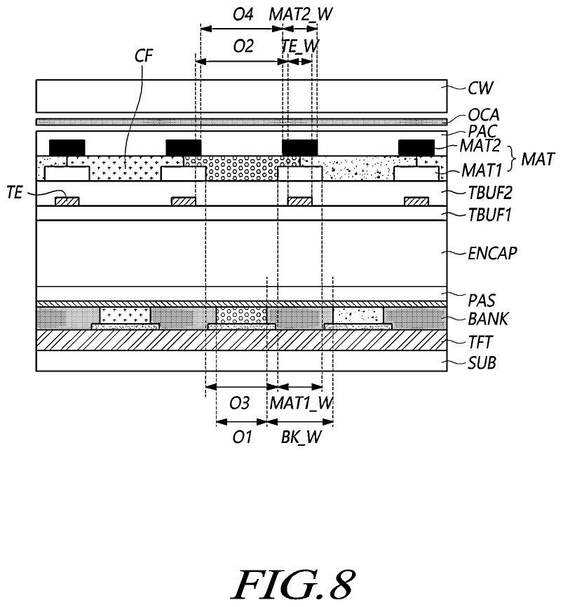

Referring to FIG. 8, part of the color filter CF can be positioned on the first matrix MAT1, and side surfaces of adjacent color filters CF11 and CF12, CF12 and CF13, or CF13 and CF11 can be in direct contact with another neighboring color filter CF on the first matrix MAT1, and the contact portion can be positioned under the second matrix MAT2. In this case, the color filter CF can include red, green, and blue, and CF 11 can correspond to red, CF12 can correspond to green, and CF13 can correspond to blue. Further, the color filters CF are illustrated in three colors in the drawings, but can be configured to correspond to three or more colors.

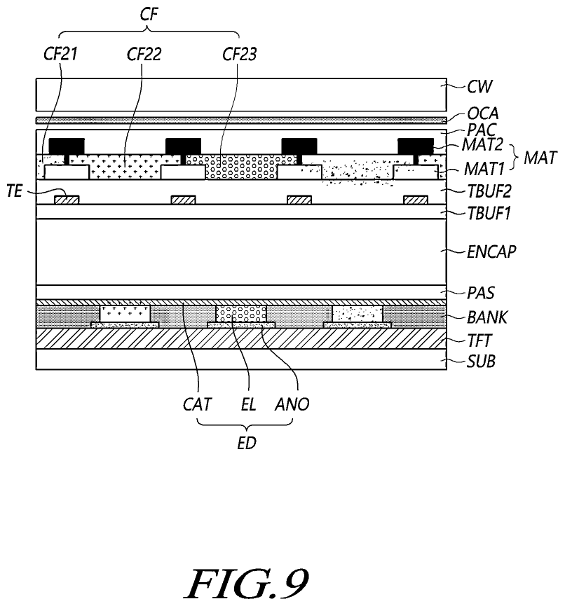

Referring to FIG. 9 which illustrates another embodiment, part of the color filter CF can be positioned on the first matrix MAT1, and side surfaces of the adjacent color filters CF21 and CF22, CF22 and CF23, or CF23 and CF21 can be positioned to be spaced apart from another neighboring color filter CF on the first matrix MAT1, the spaced-apart portions of the different color filters CF can be positioned under the second matrix MAT2, and the second matrix MAT2 can directly contact the first matrix MAT1 while filling the spaced-apart portions.

Referring to FIG. 9, the spaced-apart portions of the different color filters CF can be filled by a portion of the second matrix MAT2 that has a width different from a portion of the second matrix MAT2 on the upper surfaces of the different color filters CF. For example, the width of the portion of the second matrix MAT2 filled in the spaced-apart portions of the different color filters CF can be smaller that a width of the portion of the second matrix MAT2 on the upper surfaces of the different color filters CF, but embodiments of the disclosure are not limited thereto. For example, the width of the portion of the second matrix MAT2 filled in the spaced-apart portions of the different color filters CF can be approximately the same or greater than the width of the portion of the second matrix MAT2 on the upper surfaces of the different color filters CF. The width of the portion of the second matrix MAT2 filled in the spaced-apart portions of the different color filters CF can be approximately the same or less than a width of the first matrix MAT2.

Referring to FIG. 9, the spaced-apart portions of the different color filters CF can be filled by a portion of the first matrix MAT1 that has a width different from a portion of the first matrix MAT1 on the upper surfaces of the second touch buffer layer TBUF2. In other embodiments of the disclosure, the spaced-apart portions of the different color filters CF can be filled by another material or can remain a gap.

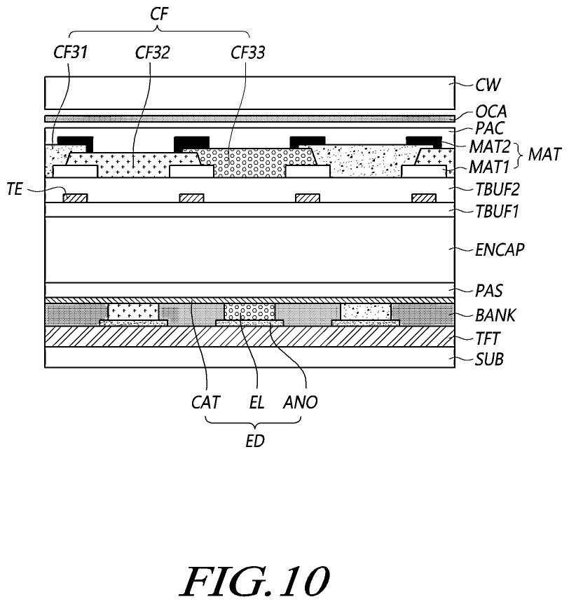

Referring to FIG. 10 which illustrates another embodiment, parts or portions of the color filters CF, CF31, CF32, and CF33 on the first matrix MAT1 can be positioned to overlap another neighboring color filter, and the overlapping portions of the different color filters can be positioned to overlap under the second matrix MAT2, and can have a width equal to or smaller than the width MAT2_W of the second matrix MAT2. For example, the second matrix MAT2 can be positioned above the portion where the first color filter CF31 and the second color filter CF32 overlap each other, and the first matrix MAT1 can be positioned under the portion where the first color filter CF31 and the second color filter CF32 overlap each other. The second matrix MAT2 can overlap a portion of the first color filter CF31 and can overlap a portion of the second color filter CF32. The first matrix MAT1 can overlap a portion of the first color filter CF31 and can overlap a portion of the second color filter CF32.

Referring to FIG. 10, the lateral portions of the different color filters CF overlap underneath the second matrix MAT2. Also, a thickness of the later portion of the color filters CF that overlap that of another color filter CF can vary. For example, a thickness of a lateral portion of the first color filter CF31 that overlap a lateral portion of the second color filter CF32 can be different from a thickness of a lateral portion of the third color filter CF33 that overlaps a lateral portion of the second color filter CF32. In various embodiments of the disclosure, thicknesses of lateral portions of the same color filter can also differ. For example, the third color filter CF33 includes lateral portions that differ in thickness on opposite sides thereof. In addition to the lateral portions of the first color filter CF31, the second color filter CF32 and the third color filter CF33 being different, thicknesses of the main portions of the first color filter CF31, the second color filter CF32 and the third color filter CF33 can also be different, but embodiments of the disclosure are not limited thereto. For example, the thicknesses of the main portions of the first color filter CF31, the second color filter CF32 and the third color filter CF33 can be the same in other embodiments of the disclosure.

Referring to FIG. 10, a thickness of the second matrix MAT2 can vary over an overlap area of lateral portions of adjacent color filters CF. For example, a thickness of the second matrix MAT2 at the overlap area of the second color filter CF32 and the third color filter CF33 can be different. As an example, a first portion of the second matrix MAT2 that contacts the second color filter CF32 can have a greater thickness than a second portion of the second matrix MAT2 that contacts the third color filter CF33, but embodiments of the disclosure are not limited thereto. In other embodiments a thickness of the first matrix MAT1 can vary over an overlap area of lateral portions of adjacent color filters CF.

The display device according to embodiments of the disclosure can have low power consumption due to lack of a polarizing plate and can effectively reduce the reflectance through multiple destructive interference by including a first matrix MAT1, a second matrix MAT2, and a color filter positioned between the first matrix MAT1 and the second matrix MAT2, thereby addressing the issues with the conventional art.

Embodiments of the disclosure described above are briefly described below.

A display device according to embodiments of the disclosure can include a substrate SUB including a display area, a light emitting element ED positioned on the substrate SUB, a bank BANK, an encapsulation layer ENCAP positioned on the light emitting element ED, a touch electrode TE positioned on the encapsulation layer ENCAP, a matrix MAT positioned on the touch electrode TE, and a color filter CF positioned on the touch electrode TE.

The matrix MAT can include a first matrix MAT1 and a second matrix MAT2. The second matrix MAT2 can be positioned on the first matrix MAT1 and can have a lower refractive index than the first matrix MAT1. Further, a portion of the color filter CF can be positioned under the second matrix MAT2 and on the first matrix MAT1. The refractive index of the color filter CF can be lower than that of the first matrix MAT1.

For example, the first matrix MAT1 can have a refractive index of 2.1 to 2.7, and the second matrix MAT2 can have a refractive index of 1.4 to 1.8.

The color filter CF can be positioned between the first matrix MAT1 and the second matrix MAT2.

The first matrix MAT1 can include white nanoparticles and black nanoparticles, and the second matrix MAT2 can include black nanoparticles. The black nanoparticles included in the second matrix MAT2 can have a larger weight ratio than the black nanoparticles included in the first matrix MAT1.

The bank BANK, the touch electrode TE, the first matrix MAT1, and the second matrix MAT2 can be positioned in a non-emission area defined by the bank BANK in the display area AA and can be positioned to overlap each other.

The bank BANK can include a first opening O1 corresponding to the light emitting element ED. The touch electrode TE can include a second opening O2 corresponding to the light emitting element ED. The first matrix MAT1 can include a third opening O3 corresponding to the light emitting element ED. The second matrix MAT2 can include a fourth opening O4 corresponding to the light emitting element ED. In this case, the second opening O2 of the touch electrode can be the same as or larger than the first opening O1 of the bank, the third opening O3 of the first matrix MAT1 can be positioned in or overlapped with the second opening O2 of the touch electrode TE, and the first opening O1 of the bank BANK can be positioned in or overlapped with the third opening O3. The fourth opening O4 of the second matrix MAT2 can be positioned in or overlapped with the second opening O2 of the touch electrode TE, and the third opening O3 of the first matrix MAT1 and the first opening O1 of the bank BANK can be positioned in or overlapped with the fourth opening O4.

The bank BANK can have a bank width BK_W having a predetermined size, the touch electrode TE can have a touch electrode width TE_W having a predetermined size, the first matrix MAT1 can have a first matrix width MAT1_W having a predetermined size, and the second matrix MAT2 can have a second matrix width MAT2_W having a predetermined size. In this case, the width TE_W of the touch electrode can be equal to or smaller than the width BK_W of the bank, the width MAT1_W of the first matrix can be equal to or larger than the width TE_W of the touch electrode and equal to or smaller than the width BK_W of the bank, and the width MAT2_W of the second matrix can be equal to or larger than the width TE_W of the touch electrode and equal to or smaller than the width BK_W of the bank and equal to or smaller than the width MAT1_W of the first matrix. In other words, the area where the second matrix is positioned can be the same as or smaller than the area where the first matrix is positioned, the area where the bank is positioned can be the same as or larger than the area where the second matrix is positioned, and the area where the touch electrode is positioned can be the same as or smaller than the area where second matrix is positioned.

A portion of the color filter CF can be positioned on the first matrix MAT1, a side surface of an adjacent color filter CF can be in direct contact with another adjacent color filter CF on the first matrix MAT1, and the contact portion can be positioned under the second matrix MAT2.

A portion of the color filter CF can be positioned to be spaced apart from another neighboring color filter CF on the first matrix MAT1, the spaced-apart portion of the different color filters CF can be positioned under the second matrix MAT2, and the second matrix MAT2 can directly contact the first matrix MAT1 while filling the spaced-apart portion.

A portion of the color filter CF on the first matrix MAT1 can be positioned to overlap another neighboring color filter, and the overlapping portion of the different color filters can be positioned under the second matrix MAT2 and can have a width equal to or smaller than the width MAT2_W of the second matrix.

An organic insulation layer PAC, an optical adhesive layer OCA, and a cover window CW can be included on the second matrix MAT2 and the color filter CF. The optical adhesive layer OCA can include, e.g., a pigment.

A display device 100 according to embodiments of the disclosure can include a substrate SUB, a bank BANK disposed on the substrate SUB and having a first opening, a matrix MAT disposed on the bank BANK and having an opening at least partially overlapping the first opening, and a color filter CF disposed in the opening of the matrix MAT.

In the display device 100 according to embodiments of the disclosure, the matrix MAT can include a first layer having a first refractive index and a second layer having a second refractive index lower than the first refractive index. Here, the first layer can be positioned closer to the substrate than the second layer. The first layer can be referred to as a first matrix MAT1, and the second layer can be referred to as a second matrix MAT2.

In the display device 100 according to embodiments of the disclosure, the first layer of the matrix MAT can be referred to as a first matrix MAT1, and the second layer of the matrix MAT can be referred to as a second matrix MAT2. The first matrix MAT1 and the second matrix MAT2 can overlap each other but can be disposed to be vertically spaced apart from each other. Alternatively, the first matrix MAT1 and the second matrix MAT2 can be disposed without being vertically spaced apart from each other. In other words, an upper surface of the first matrix MAT1 and a lower surface of the second matrix MAT2 can contact each other.

The display device 100 according to embodiments of the disclosure can further include a metal layer disposed under the matrix MAT and having an opening at least partially overlapping the first opening. Here, a signal whose voltage level changes can be applied to the metal layer at a predetermined timing. For example, the metal layer can be a touch electrode TE.

The above-described embodiments are merely examples, and it will be appreciated by one of ordinary skill in the art various changes can be made thereto without departing from the scope of the disclosure. Accordingly, the embodiments set forth herein are provided for illustrative purposes, but not to limit the scope of the disclosure, and should be appreciated that the scope of the disclosure is not limited by the embodiments. The scope of the disclosure should be construed by the following claims, and all technical spirits within equivalents thereof should be interpreted to belong to the scope of the disclosure.

What is claimed is:

1. A display device, comprising:
a substrate;
a light emitting element positioned on the substrate;
a bank dividing an emission area corresponding to the light emitting element and a non-emission area that is adjacent to the emission area, and including a first opening corresponding to the light emitting element;
an encapsulation layer positioned on the light emitting element;
a touch electrode positioned on the encapsulation layer;
a first matrix positioned on the touch electrode and a second matrix positioned on the first matrix and having a lower refractive index than the first matrix; and
a color filter positioned on the touch electrode.

2. The display device of claim 1, wherein a width of the second matrix is smaller than a width of the first matrix.

3. The display device of claim 1, wherein the first matrix, the second matrix, the touch electrode, and the bank are positioned to overlap each other.

4. The display device of claim 1, wherein the touch electrode includes a second opening, and
wherein the first opening of the bank is overlapped with the second opening of the touch electrode.

5. The display device of claim 4, wherein the first matrix includes a third opening,
wherein the second matrix includes a fourth opening, and
wherein the third opening of the first matrix and the fourth opening of the second matrix are overlapped with the second opening of the first touch electrode.

6. The display device of claim 5, wherein the third opening of the first matrix is overlapped with the fourth opening of the second matrix.

7. The display device of claim 5, wherein the first opening of the bank is overlapped the fourth opening of the second matrix, and
wherein the first opening of the bank is overlapped with the third opening of the first matrix.

8. The display device of claim 1, wherein a portion of the color filter is positioned on the first matrix, and
wherein the portion of the color filter is positioned under the second matrix.

9. The display device of claim 1, wherein the second matrix includes a black particle, and
wherein a weight ratio of the black particle included in the second matrix is larger than a weight ratio of a black particle included in the first matrix.

10. The display device of claim 1, wherein a refractive index of the first matrix is approximately 2.1 to 2.7, and
wherein a refractive index of the second matrix is approximately 1.4 to 1.8.

11. A display device, comprising:
a first substrate including;
a plurality of light emitting elements positioned on the first substrate and including a first light emitting element and a second light emitting element;
a bank dividing a first emission area of the first light emitting element and a second emission area of a second light emitting element;
an encapsulation layer positioned on the first light emitting element and the second light emitting element;
a first matrix positioned on the encapsulation layer and a second matrix positioned on the first matrix; and
a first color filter corresponding to the first emission area and a second color filter corresponding to the second emission area, on the encapsulation layer,
wherein a portion of the first color filter and a portion of the second color filter are positioned on the first matrix.

12. The display device of claim 11, wherein the portion of the first color filter positioned on the first matrix and the portion of the second color filter positioned on the first matrix are positioned under the second matrix.

13. The display device of claim 11, wherein a side surface of the first color filter contacts a side surface of the second color filter, on the first matrix.

14. The display device of claim 12, wherein a side surface of the first color filter is spaced apart from a side surface of the second color filter on the first matrix at a spaced-apart area, and
wherein in the spaced-apart area, the second matrix contacts the first matrix.

15. The display device of claim 12, wherein the portion of the second color filter positioned on the first matrix is positioned on the portion of the first color filter, and
wherein an area where the second color filter and the first color filter overlap each other is positioned on the first matrix and positioned under the second matrix.

16. The display device of claim 11, further comprising an organic insulation layer covering the second matrix, the first color filter, and the second color filter.

17. The display device of claim 11, further comprising:
a second substrate on the first substrate; and
an organic layer between the first substrate and the second substrate,
wherein the organic layer includes a dye or a pigment.

18. The display device of claim 17, wherein the organic layer has adhesiveness.

19. The display device of claim 1, wherein the display device lacks a polarizing plate.

20. A display device, comprising:
a substrate;
a light emitting element on the substrate;
a bank defining an emission area corresponding to the light emitting element;
an encapsulation layer on the light emitting element;
a touch electrode on the encapsulation layer;
a first matrix on the touch electrode and a second matrix on the first matrix and having a different lower refractive index from that of the first matrix; and
a color filter interposed between the first matrix and the second matrix over the touch electrode.
